(19) United States
(12) Patent Application Publication
(10) Pub. No.: US 2023/0055085 A1
(43) Pub. Date: Feb. 23, 2023

(54) Cooling Electronic Cabinet Assembly

(71) Applicant: Mathew Zaagsma, Davenport, WA (US)

(72) Inventor: Mathew Zaagsma, Davenport, WA (US)

(21) Appl. No.: 17/405,376

(22) Filed: Aug. 18, 2021

(51) Int. Cl. H05K 5/02; B01D 46/00; F24F 1/028

(52) U.S. Cl. CPC H05K 5/0213; B01D 46/0049; B01D 46/002; B01D 46/0006; F24F 1/028; B01D 2273/30; B01D 2279/45

(57) ABSTRACT

A cooling electronic cabinet assembly includes a cabinet that has a plurality of storage compartments that is each defined within an interior of the cabinet to store an electronic device. The cabinet has a plurality of air holes each being integrated into the cabinet. A plurality of blowers is each coupled to the cabinet and each of the blowers is aligned with a respective air hole. Each of the blowers urges air in a first direction when the blowers are turned on to urge the air over the electronic devices in the cabinet for cooling the electronic devices. A plurality of filter housings is each coupled to the cabinet and each of the filter housings is aligned with a respective one of the air holes. A plurality of filters is each of the filters is removably insertable into a respective one of the filter housings to filter particles from the air is blown through the filters.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to cooling cabinet device and more particularly pertains to a new cooling cabinet device for blowing air over electronic devices stored in the cooling cabinet. The device includes a cabinet for storing electronic devices and a plurality of fans that are each attached to the cabinet. The device additionally includes a plurality of filter housings and a plurality of filters that is each insertable into respective filter housings. Each of the filter housings is aligned with a respective fan for filtering air blown by the respective fan.

### (2) Description of Related Art Including Information Disclosed Under 37 CFR 1.97 and 1.98

The prior art relates to cooling cabinet devices including a pad with fans integrated into the pad for cooling a laptop computer that is positioned on the pad. The prior art discloses a cooling device that blows cooled air through a vent in a floor for cooling electronic equipment that is positioned on the floor. The prior art discloses a cabinet with fans for blowing air from a first area in the cabinet into a second area in the cabinet. The prior art discloses a liquid cooled heat sink for cooling a notebook computer. The prior art discloses a cabinet which includes a closed loop refrigeration system for cooling electronic equipment.

### BRIEF SUMMARY OF THE INVENTION

An embodiment of the disclosure meets the needs presented above by generally comprising a cabinet that has a plurality of storage compartments that is each defined within an interior of the cabinet to store an electronic device. The cabinet has a plurality of air holes each being integrated into the cabinet. A plurality of blowers is each coupled to the cabinet and each of the blowers is aligned with a respective air hole. Each of the blowers urges air in a first direction when the blowers are turned on to urge the air over the electronic devices in the cabinet for cooling the electronic devices. A plurality of filter housings is each coupled to the cabinet and each of the filter housings is aligned with a respective one of the air holes. A plurality of filters is each of the filters is removably insertable into a respective one of the filter housings to filter particles from the air is blown through the filters.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front view of a cooling electronic cabinet assembly according to an embodiment of the disclosure.

FIG. 2 is a back phantom view of an embodiment of the disclosure.

FIG. 3 is a left side view of an embodiment of the disclosure.

FIG. 4 is an exploded perspective view of an embodiment of the disclosure.

FIG. 5 is a perspective view of an alternative embodiment of the disclosure.

### DETAILED DESCRIPTION OF THE INVENTION

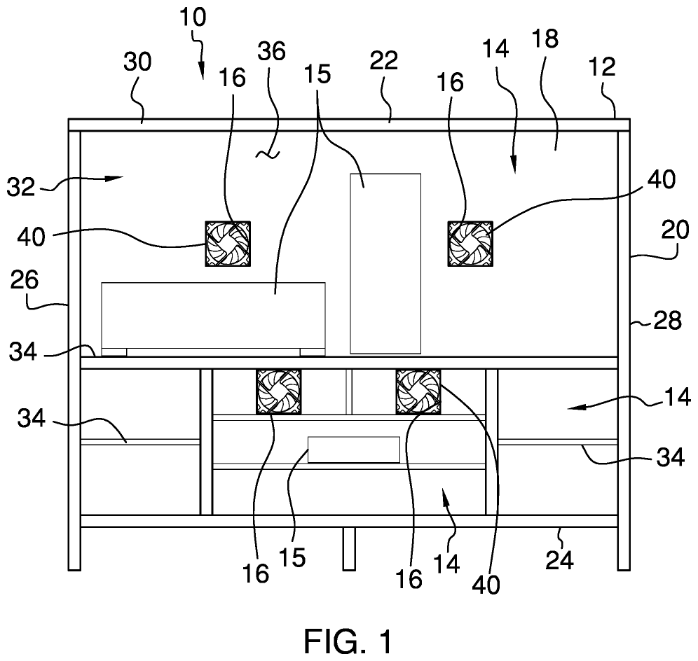

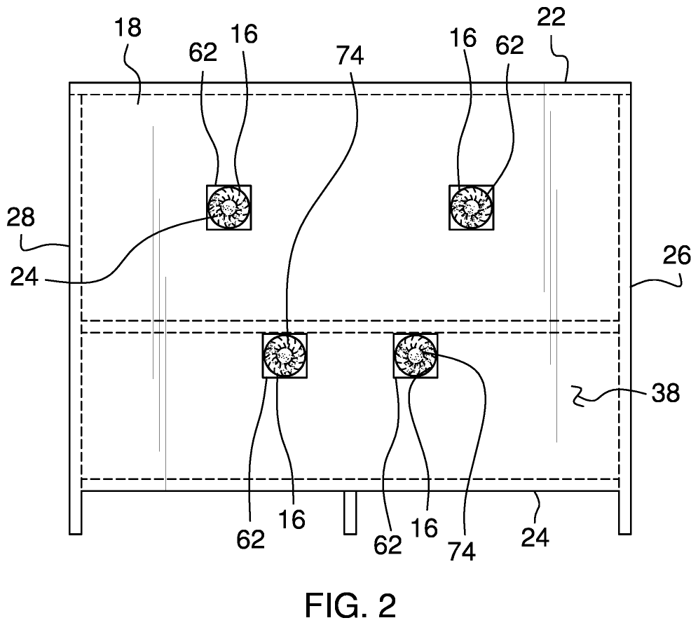

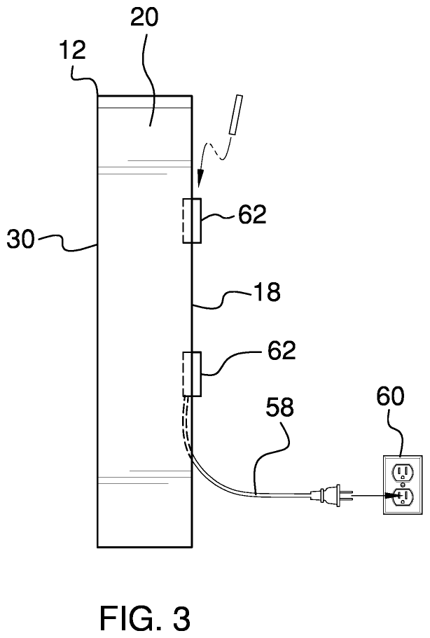

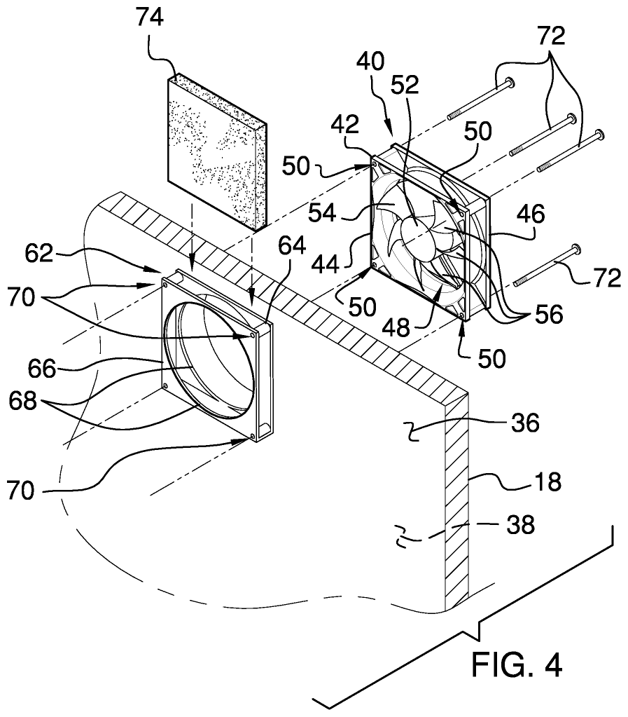

With reference now to the drawings, and in particular to FIGS. 1 through 5 thereof, a new cooling cabinet device embodying the principles and concepts of an embodiment of the disclosure and generally designated by the reference numeral 10 will be described.

As best illustrated in FIGS. 1 through 5, the cooling electronic cabinet assembly 10 generally comprises a cabinet 12 that has a plurality of storage compartments 14 each being defined within an interior of the cabinet 12. Each of the storage compartments 14 can store an electronic device 15, such as a gaming system, a personal computer, a television or any other type of electronic entertainment device. The cabinet 12 has a plurality of air holes 16 each integrated into the cabinet 12.

The cabinet 12 has a rear wall 18 and a perimeter wall 20 extending forwardly from the rear wall 18, and the perimeter wall 20 has a top side 22, a bottom side 24, a first lateral side 26 and a second lateral side 28. The perimeter wall 20 has a distal edge 30 with respect to the rear wall 18 which defines an entrance 32 into the cabinet 12. Additionally, the cabinet 12 has a plurality of shelves 34 each extending between the first lateral side 26 and the second lateral side 28. The shelves 34 are spaced apart from each other and are distributed between the top side 22 and the bottom side 24 thereby defining the plurality of storage compartments 14 between respective pairs of the shelves 34. Each of the plurality of air holes 16 extends through the rear wall 18 to pass air through the rear wall 18. Furthermore, each of the air holes 16 is aligned with a respective one of the compartments, and the rear wall 18 has a front surface 36 and a rear surface 38.

A plurality of blowers 40 is provided and each of the blowers 40 is coupled to the cabinet 12. Each of the blowers 40 is aligned with a respective air hole 16 and each of the blowers 40 urges air in a first direction when the blowers 40 are turned on. In this way each of the blowers 40 can urge the air over the electronic devices 15 in the cabinet 12 for cooling the electronic devices 15. Each of the blowers 40 comprises a fan housing 42 which has a forward side 44 and a rearward side 46, and the fan housing 42 has an opening 48 extending through the rearward side 46 and the forward side 44. The fan housing 42 has a plurality of screw holes 50 each extending through the forward side 44 and the rearward side 46. Each of the screw holes 50 is aligned with a respective one of four corners of the fan housing 42. Additionally, the forward side 44 of the fan housing 42 is positioned against the front surface 36 of the rear wall 18 and the fan housing 42 associated with each of the blowers 40 is aligned with a respective one of the air holes 16.

Each of the blowers 40 includes a motor 52 that is positioned in the fan housing 42 and the motor 52 rotates in a first direction when the motor 52 is turned on. Each of the blowers 40 includes a fan 54 that is coupled to the motor 52 such that the fan 54 is rotated when the motor 52 rotates in the first direction. The fan 54 has a plurality of blades 56 to blow air through a respective air hole 16 when the fan 54 is rotated. The motor 52 associated with each of the blowers 40 may comprise an electric motor or the like. Additionally, the motor 52 associated with each of the blowers 40 might include a power cord 58 that is pluggable into a power source 60 comprising a female electrical outlet.

A plurality of filter housings 62 is provided and each of the filter housings 62 is coupled to the cabinet 12. Each of the filter housings 62 is coupled to the cabinet 12 and each of the filter housings 62 is aligned with a respective one of the air holes 16. Furthermore, each of the filter housings 62 has a first wall 64 that is spaced from a second wall 66, and each of the first wall 64 and the second wall 66 has an aperture 68 extending therethrough. The aperture 68 in the first wall 64 is aligned with the aperture 68 in the second wall 66. Additionally, the first wall 64 abuts the rear surface 38 of the rear wall 18 of the cabinet 12 such that the aperture 68 in each of the first wall 64 and the second wall 66 is aligned with the respective air hole 16 such that the fan 54 in a respective one of the blowers 40 can blow air through the aperture 68 in each of the first wall 64 and the second wall 66.

Each of the filter housings 62 has a plurality of screw holes 70 each extending through the first wall 64 and the second wall 66. Each of the screw holes 70 in each of the first wall 64 and the second wall 66 is aligned with a respective one of four corners of a respective filter housing 62. Additionally, each of the screw holes 70 associated with each of the filter housings 62 is aligned with a respective one of the screw holes 50 in a respective one of the fan housings 42. A plurality screws 72 is provided and each of the screws 72 extends through a respective screw hole 50 associated with a respective one of the fan housings 42 and a respective screw hole 70 associated with a respective one of the filter housings 62 for attaching the respective fan housing 42 and the respective filter housing 62 to the rear wall 18 of the cabinet 12.

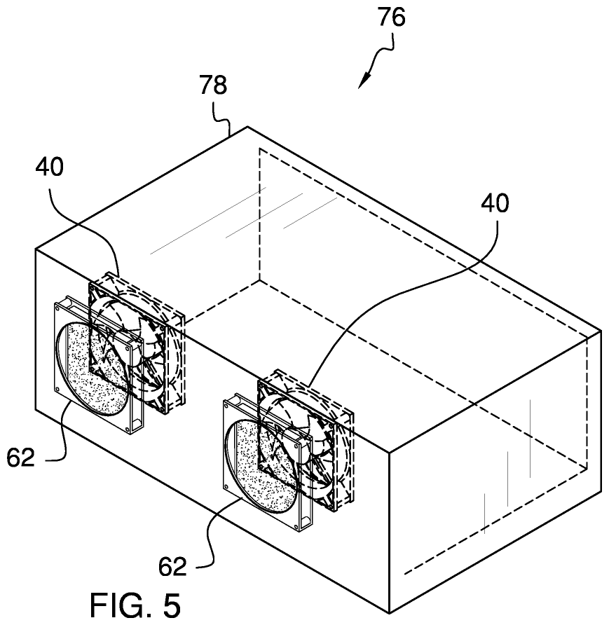

A plurality of filters 74 is provided and each of the filters 74 is removably insertable into a respective one of the filter housings 62. Each of the filters 74 is comprised of an air permeable material to filter particles from the air being blown through the filters 74. In this way the filters 74 inhibit dust from collecting on the electronic devices 15 in the cabinet 12. Each of the filters 74 is slidable between the first wall 64 and the second wall 66 of the respective filter housing 62. Additionally, the air permeable material of which each of the filters 74 is comprised may be foam rubber, compressed fibers or other type of material commonly associated with air filters. In an alternative embodiment 76 as is most clearly shown in FIG. 5, the cabinet 12 might comprise a box 78 with a single storage compartment 14 for storing a single electronic device 15.

In use, each of the electronic devices 15 is positioned in a respective one of the storage compartments 14 in the cabinet 12. In this way each of the blowers 40 can blow air over the electronic devices 15 in order to cool the electronic devices 15. Thus, the electronic devices 15 can operate efficiently and without the danger of overheating that could potentially result from storing the electronic devices 15 in the cabinet 12. Additionally, the filter 74 in each of the filter housings 62 ensures that the electronic devices 15 do not become covered with dust. The filter 74 in each of the filter housings 62 can be replaced or cleaned with the filter 74 in each of the filter housings 62 becomes filled with dust.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A cooling electronic cabinet assembly for storing electronic devices and blowing air over the electronic devices for cooling the electronic devices, said assembly comprising:
a cabinet having a plurality of storage compartments each being defined within an interior of said cabinet wherein each of said storage compartments is configured to store an electronic device, said cabinet having a plurality of air holes each being integrated into said cabinet;
a plurality of blowers, each of said blowers being coupled to said cabinet, each of said blowers being aligned with a respective air hole, each of said blowers urging air in a first direction when said blowers are turned on wherein each of said blowers is configured to urge the air over the electronic devices in said cabinet for cooling the electronic devices;
a plurality of filter housings, each of said filter housing being coupled to said cabinet, each of said filter housings being aligned with a respective one of said air holes; and
a plurality of filters, each of said filters being removably insertable into a respective one of said filter housings, each of said filters being comprised of an air permeable material wherein each of said filters is configured to filter particles from the air being blown through said filters thereby inhibiting dust from collecting on the electronic devices in said cabinet.

2. The assembly according to claim 1, wherein said cabinet has a rear wall and a perimeter wall extending forwardly from said rear wall, said perimeter wall having a top side, a bottom side, a first lateral side and a second lateral side, said perimeter wall having a distal edge with respect to said rear wall which defines an entrance into said cabinet, said cabinet having a plurality of shelves each extending between said first lateral side and said second lateral side, said shelves being spaced apart from each other and being distributed between said top side and said bottom side thereby defining said plurality of storage compartments between respective pairs of said shelves, each of said plurality of air holes extending through said rear wall wherein each of said air holes is configured to pass air through said rear wall, each of said air holes being aligned with a respective one of said compartments, said rear wall having a front surface and a rear surface.

3. The assembly according to claim 2, wherein each of said blowers comprises a fan housing having a forward side and a rearward side, said fan housing having an opening extending through said rearward side and said forward side, said fan housing having a plurality of screw holes each extending through said forward side and said rearward side, each of said screw holes being aligned with a respective one of four corners of said fan housing said forward side of said fan housing being positioned against said front surface of said rear wall, said fan housing associated with each of said blowers being aligned with a respective one of said air holes.

4. The assembly according to claim 3, wherein each of said blowers comprises:
a motor being positioned in said fan housing, said motor rotating in a first direction when said motor is turned on; and
a fan being coupled to said motor such that said fan is rotated when said motor rotates in said first direction, said fan having a plurality of blades wherein each of said blades is configured to blow air through a respective air hole when said fan is rotated.

5. The assembly according to claim 4, wherein:
each of said filter housings has a first wall being spaced from a second wall, each of said first wall and said second wall having an aperture extending therethrough, said aperture in said first wall being aligned with said aperture in said second wall, said first wall abutting said rear surface of said rear wall of said cabinet such that said aperture in each of said first wall and said second wall is aligned with said respective air hole wherein said fan in a respective one of said blowers is configured to blow air through said aperture in each of said first wall and said second wall; and
each of said filter housings has a plurality of screw holes each extending through said first wall and said second wall, each of said screw holes in each of said first wall and said second wall being aligned with a respective one of four corners of a respective filter housing, each of said screw holes associated with each of said filter housings being aligned with a respective one of said screw holes in a respective one of said fan housings.

6. The assembly according to claim 5, further comprising a plurality screws, each of said screws extending through a respective screw hole associated with a respective one of said fan housings and a respective screw hole associated with a respective one of said filter housings for attaching said respective fan housing and said respective filter housing to said rear wall of said cabinet.

7. The assembly according to claim 5, wherein each of said filters is slidable between said first wall and said second wall of said respective filter housing.

8. A cooling electronic cabinet assembly for storing electronic devices and blowing air over the electronic devices for cooling the electronic devices, said assembly comprising:
a cabinet having a plurality of storage compartments each being defined within an interior of said cabinet wherein each of said storage compartments is configured to store an electronic device, said cabinet having a plurality of air holes each being integrated into said cabinet, said cabinet having a rear wall and a perimeter wall extending forwardly from said rear wall, said perimeter wall having a top side, a bottom side, a first lateral side and a second lateral side, said perimeter wall having a distal edge with respect to said rear wall which defines an entrance into said cabinet, said cabinet having a plurality of shelves each extending between said first lateral side and said second lateral side, said shelves being spaced apart from each other and being distributed between said top side and said bottom side thereby defining said plurality of storage compartments between respective pairs of said shelves, each of said plurality of air holes extends through said rear wall wherein each of said air holes is configured to pass air through said rear wall, each of said air holes being aligned with a respective one of said compartments, said rear wall having a front surface and a rear surface;
a plurality of blowers, each of said blowers being coupled to said cabinet, each of said blowers being aligned with a respective air hole, each of said blowers urging air in a first direction when said blowers are turned on wherein each of said blowers is configured to urge the air over the electronic devices in said cabinet for cooling the electronic devices, each of said blowers comprising:
a fan housing having a forward side and a rearward side, said fan housing having an opening extending through said rearward side and said forward side, said fan housing having a plurality of screw holes each extending through said forward side and said rearward side, each of said screw holes being aligned with a respective one of four corners of said fan housing said forward side of said fan housing being positioned against said front surface of said rear wall, said fan housing associated with each of said blowers being aligned with a respective one of said air holes;
a motor being positioned in said fan housing, said motor rotating in a first direction when said motor is turned on; and
a fan being coupled to said motor such that said fan is rotated when said motor rotates in said first direction, said fan having a plurality of blades wherein each of said blades is configured to blow air through a respective air hole when said fan is rotated;
a plurality of filter housings, each of said filter housing being coupled to said cabinet, each of said filter housings being aligned with a respective one of said air holes, each of said filter housings having a first wall being spaced from a second wall, each of said first wall and said second wall having an aperture extending therethrough, said aperture in said first wall being aligned with said aperture in said second wall, said first wall abutting said rear surface of said rear wall of said cabinet such that said aperture in each of said first wall and said second wall is aligned with said respective air hole wherein said fan in a respective one of said blowers is configured to blow air through said aperture in each of said first wall and said second wall, each of said filter housings having a plurality of screw holes each extending through said first wall and said second wall, each of said screw holes in each of said first wall and said second wall being aligned with a respective one of four corners of a respective filter housing, each of said screw holes associated with each of said filter housings being aligned with a respective one of said screw holes in a respective one of said fan housings;
a plurality screws, each of said screws extending through a respective screw hole associated with a respective one of said fan housings and a respective screw hole associated with a respective one of said filter housings for attaching said respective fan housing and said respective filter housing to said rear wall of said cabinet; and
a plurality of filters, each of said filters being removably insertable into a respective one of said filter housings, each of said filters being comprised of an air permeable material wherein each of said filters is configured to filter particles from the air being blown through said filters thereby inhibiting dust from collecting on the electronic devices in said cabinet, each of said filters being slidable between said first wall and said second wall of said respective filter housing.
